(19) United States
(12) Patent Application Publication
(10) Pub. No.: US 2023/0076919 A1
(43) Pub. Date: Mar. 9, 2023

(54) SENSING AND DIGITAL DISPLAY TYPE WEIGHING AND CODE SCANNING INTEGRATED MACHINE WITH DAMPING AND DUST-PROOF SMART CASE

(71) Applicant: Hoi Lam Ray LAU, Hong Kong (CN)

(72) Inventor: Hoi Lam Ray LAU, Hong Kong (HK)

(21) Appl. No.: 17/794,779

(22) PCT Filed: Jul. 27, 2021
(86) PCT No.: PCT/CN2021/108610

§ 371 Date: Jul. 22, 2022

(30) Foreign Application Priority Data
May 29, 2020 (CN) 202010479511.1

(51) Int. Cl. G01G 21/28; G01G 21/22; G01G 21/30

(52) U.S. Cl. CPC G01G 21/283; G01G 21/22; G01G 21/30

(57) ABSTRACT

A sensing and digital display type weighing and code scanning integrated machine with a damping and dust-proof smart case includes a case device. A weigher is placed at an upper end of the case device. A code scanning device is fixedly connected to the upper end of the case device. The case device includes a case, a guide hole, a threaded hole, a through groove, a groove, a fan, a case door, a magnet, a guide rod, a first spring, a host base, a first clamping groove, a computer host, a filter cartridge, a circular groove and an efficient filter screen. The case door is hinged to the case. The magnet is fixedly connected to the case door. The guide rod is slidably nested in the case. The host base is fixedly connected to an upper end of the guide rod. The computer host is clamped in the host base.

### FIELD OF THE INVENTION

The present invention relates to the technical field of weighing devices, and more particularly to a sensing and digital display type weighing and code scanning integrated machine with a damping and dust-proof smart case.

### BACKGROUND OF THE INVENTION

With the continuous advancement of science and technology, traditional weighing devices have been unable to meet the needs of modern industry. At present, in some factories, codes of packaged products need to be scanned mostly by weighing and code scanning integrated devices. In general, a weighing and code scanning machine should be equipped with a weigher, a code scanner and a computer to realize data interconnection, which greatly improves the work efficiency.

However, a computer display of the weighing and code scanning machine is inconvenient to dismount, which does not facilitate overhauling. In addition, a computer host is usually placed outside a body of the weighing and code scanning machine, such that the host is easily affected by dust, high temperature and vibration to shorten the service life.

### SUMMARY OF THE INVENTION

An objective of the present invention is to provide a sensing and digital display type weighing and code scanning integrated machine with a damping and dust-proof smart case, so as to solve the problem raised in the above background.

In order to achieve the above objective, the present invention provides the following technical solution: a sensing and digital display type weighing and code scanning integrated machine with a damping and dust-proof smart case, and the integrated machine including a case device, wherein a weigher is placed at an upper end of the case device, and a code scanning device is fixedly connected to the upper end of the case device;

the case device includes a case, a guide hole, a threaded hole, a through groove, a groove, a fan, a case door, a magnet, a guide rod, a first spring, a host base, a first clamping groove, a computer host, a filter cartridge, a circular groove and an efficient filter screen, wherein the case door is hinged to the case, the magnet is fixedly connected to a surface of the case door, the guide rod is slidably nested in the case, the host base is fixedly connected to an upper end of the guide rod, the computer host is clamped in the host base, the case is formed with the threaded hole, the through groove and the groove, the filter cartridge is in threaded connection with the interior of the threaded hole, and the efficient filter screen is adhered in the filter cartridge;

the weigher is provided with a display screen, a sensor is fixedly connected to an upper end of the weigher, a tray is clamped to an upper end of the sensor, the tray is formed with a positioning groove, and the positioning groove is in clamped connection with the sensor; and

the code scanning device includes a support column, a fixed seat, a second clamping groove, a computer display, a support frame, a through hole, a sliding rod, a second spring, a movable clamping seat, a third clamping groove and a code scanner, wherein the support column is fixedly connected with the case, the fixed seat is fixedly connected to a left end of the support column, the computer display is clamped in the fixed seat, the support frame is fixedly connected to an upper end of the support column, the sliding rod is slidably nested in the support frame, the movable clamping seat is fixedly connected to a lower end of the sliding rod, the movable clamping seat is in clamped connection with the computer display, and the code scanner is fixedly connected to a lower end of the support frame.

Preferably, the fan is fixedly connected to an upper end of the case, and the fan is connected with an external power supply by a wire.

Preferably, the case is formed with the guide hole, and the guide rod is slidably nested in the guide hole.

Preferably, the first spring is sleeved on outer side of the guide rod, an upper end of the first spring is in contact with a lower end of the host base, and a lower end of the first spring is in contact with the case.

Preferably, the host base is formed with the first clamping groove, and the first clamping groove is in clamped connection with the computer host.

Preferably, the filter cartridge is formed with the circular groove, and the efficient filter screen is adhered in the circular groove.

Preferably, the fixed seat is formed with the second clamping groove, and the second clamping groove is in clamped connection with the computer display.

Preferably, the support frame is formed with the through hole, the through hole is slidably nested with the sliding rod, the second spring is sleeved on an outer side of the sliding rod, an upper end of the second spring is in contact with a lower end of the support frame, and a lower end of the second spring is in contact with an upper end of the movable clamping seat.

Preferably, the movable clamping seat is formed with the third clamping groove, and the third clamping groove is in clamped connection with the computer display.

Compared with the prior art, the present invention has the following beneficial effects: the display of the weighing and code scanning integrated machine is convenient to dismount, thereby facilitating overhauling; and the influence of high temperature, dust and vibration to the service life of the integrated machine is reduced as the case device is capable of cooling the computer host and has dust-proof and damping effects.

### BRIEF DESCRIPTION OF THE DRAWINGS

The present invention will become more readily apparent to those ordinarily skilled in the art after reviewing the following detailed description and accompanying drawings, in which:

FIG. 1 is a schematic diagram of an overall structure of a sensing and digital display type weighing and code scanning integrated machine with a damping and dust-proof smart case according to the present invention;

FIG. 2 is an enlarged view of area A in FIG. 1;

FIG. 3 is an enlarged view of area B in FIG. 1;

FIG. 4 is an enlarged view of area C in FIG. 1;

FIG. 5 is an enlarged view of area D in FIG. 1;

FIG. 6 is a top view of a host base of the sensing and digital display type weighing and code scanning integrated machine with the damping and dust-proof smart case according to the present invention;

FIG. 7 is a top view of a fixed seat of the sensing and digital display type weighing and code scanning integrated machine with the damping and dust-proof smart case according to the present invention; and

FIG. 8 is a working principle diagram of a weigher of the sensing and digital display type weighing and code scanning integrated machine with the damping and dust-proof smart case according to the present invention.

In the figures, the reference numbers are as follows: 1 denotes a case device; 11 denotes a case; 12 denotes a guide hole; 13 denotes a threaded hole; 14 denotes a through groove; 15 denotes a groove; 16 denotes a fan; 17 denotes a case door; 18 denotes a magnet; 19 denotes a guide rod; 110 denotes a first spring; 111 denotes a host base; 112 denotes a first clamping groove; 113 denotes a computer host; 114 denotes a filter cartridge; 115 denotes a circular groove; 116 denotes an efficient filter screen; 2 denotes a weigher; 21 denotes a display screen; 22 denotes a sensor; 23 denotes a tray; 24 denotes a positioning groove; 3 denotes a code scanning device; 31 denotes a support column; 32 denotes a fixed seat; 33 denotes a second clamping groove; 34 denotes a computer display; 35 denotes a support frame; 36 denotes a through hole; 37 denotes a sliding rod; 38 denotes a second spring; 39 denotes a movable clamping seat; 310 denotes a third clamping groove; and 311 denotes a code scanner.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

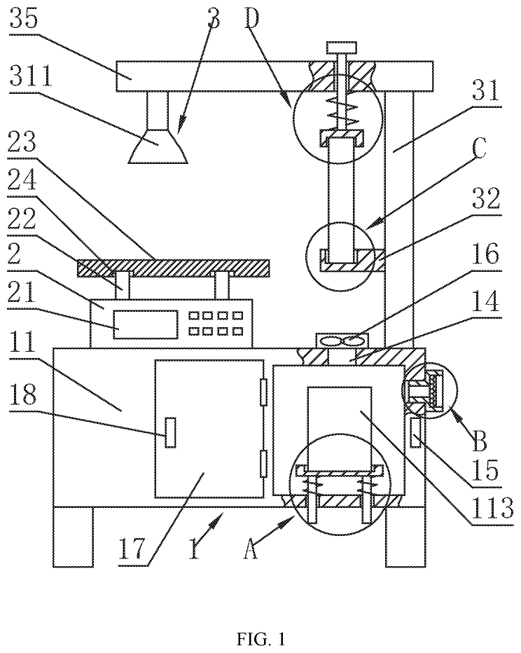

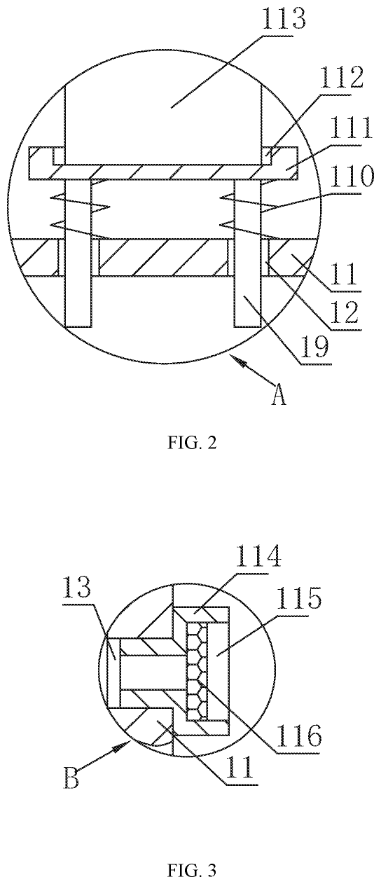

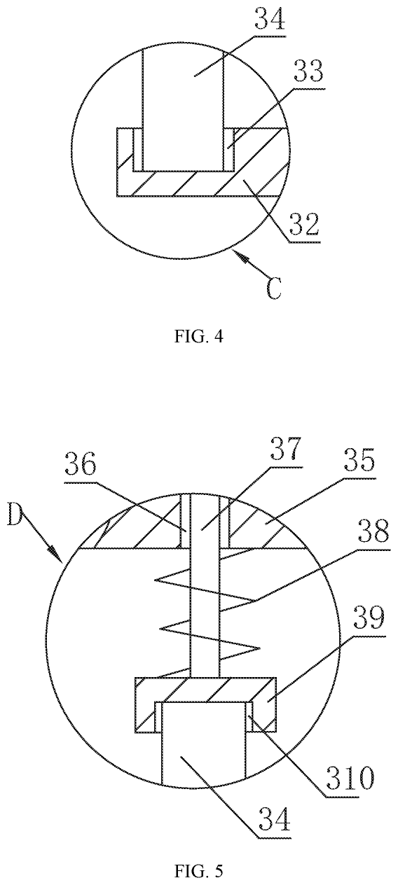

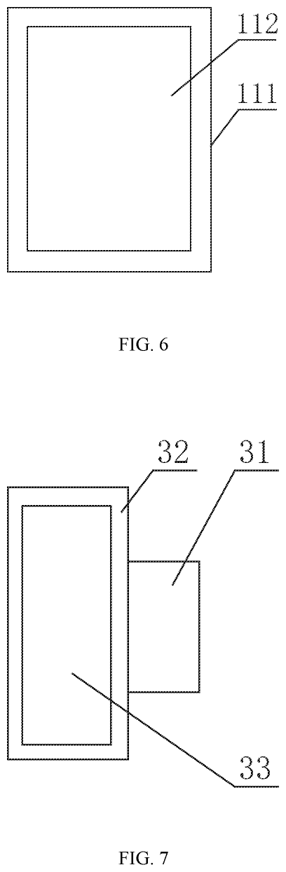

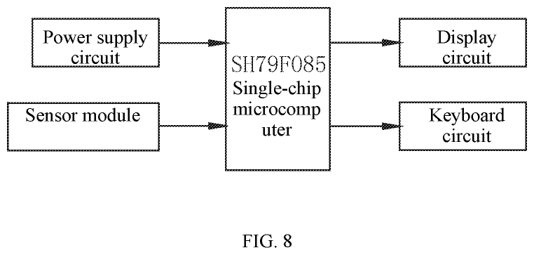

Refer to FIGS. 1 to 8. The present invention provides a technical solution of a sensing and digital display type weighing and code scanning integrated machine with a damping and dust-proof smart case. The integrated machine includes a case device 1. A weigher 2 is placed at an upper end of the case device 1 for weighing items, which belongs to the prior art. A code scanning device 3 is fixedly connected to the upper end of the case device 1.

The case device 1 includes a case 11, a guide hole 12, a threaded hole 13, a through groove 14, a groove 15, a fan 16, a case door 17, a magnet 18, a guide rod 19, a first spring 110, a host base 111, a first clamping groove 112, a computer host 113, a filter cartridge 114, a circular groove 115 and an efficient filter screen 116. The fan 16 is fixedly connected to an upper end of the case 11. The fan 16 is connected with an external power supply by a wire. The fan 16 has a model number of DHBFG, belongs to the prior art and is configured to discharge air in the case 11. The case door 17 is hinged to the case 11, the magnet 18 is fixedly connected to a surface of the case door 17, and the magnet 18 is configured to suck the groove 15 to close the case door 17. The guide rod 19 is slidably nested in the case 11. The case 11 is formed with the guide hole 12. The guide rod 19 is slidably nested in the guide hole 12. The guide hole 12 is configured to guide the guide rod 19. The first spring 110 is sleeved on outer side of the guide rod 19. An upper end of the first spring 110 is in contact with a lower end of the host base 111. A lower end of the first spring 110 is in contact with the case 11. The first spring 110 has a damping effect. The host base 111 is fixedly connected to an upper end of the guide rod 19. The computer host 113 is clamped in the host base 111. The host base 111 is formed with the first clamping groove 112. The first clamping groove 112 is in clamped connection with the computer host 113 and is configured to place the computer host 113. The case 11 is formed with the threaded hole 13, the through groove 14 and the groove 15. The filter cartridge 114 is in threaded connection with the interior of the threaded hole 13. The efficient filter screen 116 is adhered in the filter cartridge 114. The filter cartridge 114 is formed with the circular groove 115. The efficient filter screen 116 is adhered in the circular groove 115 to filter dust in the air, thereby preventing the dust from entering the case 11 to affect the computer host 113.

The weigher 2 is provided with a display screen 21. A sensor 22 is fixedly connected to an upper end of the weigher 2. An SH79F085 single-chip microcomputer is arranged in the weigher 2. The SH79F085 single-chip microcomputer is connected with a power supply circuit. The SH79F085 single-chip microcomputer is connected with a sensor module. The SH79F085 single-chip microcomputer is connected with a display circuit. The SH79F085 single-chip microcomputer is connected with a keyboard circuit of the weigher 2. The aforementioned configuration belongs to the prior art. A tray 23 is clamped to an upper end of the sensor 22. The tray 23 is formed with a positioning groove 24. The positioning groove 24 is in clamped connection with the sensor 22. When being placed on the tray 23, a heavy object exerts a pressure on the sensor 22 under the support of the tray 23. The sensor 22 transmits information to the SH79F085 single-chip microcomputer by the sensor module. The SH79F085 single-chip microcomputer processes the information, and then the display screen 21 displays a weighing result by the display circuit. Related settings are input to a keyboard on the weigher 2, the information is transmitted to the SH79F085 single-chip microcomputer by the keyboard circuit, and then the SH79F085 single-chip microcomputer modifies relevant parameters.

The code scanning device 3 includes a support column 31, a fixed seat 32, a second clamping groove 33, a computer display 34, a support frame 35, a through hole 36, a sliding rod 37, a second spring 38, a movable clamping seat 39, a third clamping groove 310 and a code scanner 311. The support column 31 is fixedly connected with the case 11. The fixed seat 32 is fixedly connected to a left end of the support column 31. The computer display 34 is clamped in the fixed seat 32. The fixed seat 32 is formed with the second clamping groove 33. The second clamping groove 33 is in clamped connection with the computer display 34 and is configured to install the computer display 34. The support frame 35 is fixedly connected to an upper end of the support column 31. The sliding rod 37 is slidably nested in the support frame 35. The support frame 35 is formed with the through hole 36. The through hole 36 is slidably nested with the sliding rod 37. The through hole 36 is configured to guide the sliding rod 37. The second spring 38 is sleeved on an outer side of the sliding rod 37. An upper end of the second spring 38 is in contact with a lower end of the support frame 35. A lower end of the second spring 38 is in contact with an upper end of the movable clamping seat 39. The second spring 38 is capable of compressing an elastic force, such that the movable clamping seat 39 can clamp the computer display 34. The movable clamping seat 39 is connected to a lower end of the sliding rod 37. The movable clamping seat 39 is in clamped connection with the computer display 34. The movable clamping seat 39 is formed with the third clamping groove 310. The third clamping groove 310 is in clamped connection with the computer display 34, such that the movable clamping seat 39 and the computer display 34 can be conveniently clamped. The code scanner 311 is fixedly connected to a lower end of the support frame 35, is configured to scan codes of objects, and belongs to the prior art.

During the specific implementation of the present invention, when the machine is in operation, the case door 17 is first deflected to the right and until the magnet 18 on the case door 17 sucks the groove 15 of the case 11, the case door 17 can be closed to seal the case 11. Then, after the power supply is connected, the fan 16 is in operation. A lot of heat is generated when the computer host 113 is in operation, thus, under the action of the fan 16, the air in the case 11 can be discharged to take away the heat, and the external air can enter the case 11 through the efficient filter screen 116, the filter cartridge 114 and the threaded hole 13 in sequence to realize ventilation and prevent the excessively high temperature of the computer host 113 from affecting the service life of the machine. Meanwhile, the dust is filtered by the efficient filter screen 116 to prevent the dust from entering the case 11 to affect the computer host 113. Vibration may occur when the computer host 113 works. Under the damping effect of the first spring 110, the vibration of the computer host 113 can be reduced, and the impact of the vibration on the service life of the computer host 113 can be weakened. When the computer display 34 fails and needs to be dismounted, the sliding rod 37 is moved up, the sliding rod 37 moves up along the through hole 36, the sliding rod 37 drives the movable clamping seat 39 to move up, the movable clamping seat 39 compresses the second spring 38, the movable clamping seat 39 leaves the computer display 34, and then the computer display 34 can be taken out from the second clamping groove 33 in the fixed seat 32, such that the dismounting is convenient and fast, and thus the overhauling is facilitated.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A sensing and digital display type weighing and code scanning integrated machine with a damping and dust-proof smart case, the sensing and digital display type weighing and code scanning integrated machine comprising a case device (1), wherein a weigher (2) is placed at an upper end of the case device (1), and a code scanning device (3) is fixedly connected to the upper end of the case device (1);
the case device (1) comprises a case (11), a guide hole (12), a threaded hole (13), a through groove (14), a groove (15), a fan (16), a case door (17), a magnet (18), a guide rod (19), a first spring (110), a host base (111), a first clamping groove (112), a computer host (113), a filter cartridge (114), a circular groove (115) and an efficient filter screen (116), wherein the case door (17) is hinged to the case (11), the magnet (18) is fixedly connected to a surface of the case door (17), the guide rod (19) is slidably nested in the case (11), the host base (111) is fixedly connected to an upper end of the guide rod (19), the computer host (113) is clamped in the host base (111), the case (11) is formed with the threaded hole (13), the through groove (14) and the groove (15), the filter cartridge (114) is in threaded connection with the interior of the threaded hole (13), and the efficient filter screen (116) is adhered in the filter cartridge (114);
the weigher (2) is provided with a display screen (21), a sensor (22) is fixedly connected to an upper end of the weigher (2), a tray (23) is clamped to an upper end of the sensor (22), the tray (23) is formed with a positioning groove (24), and the positioning groove (24) is in clamped connection with the sensor (22); and
the code scanning device (3) comprises a support column (31), a fixed seat (32), a second clamping groove (33), a computer display (34), a support frame (35), a through hole (36), a sliding rod (37), a second spring (38), a movable clamping seat (39), a third clamping groove (310) and a code scanner (311), wherein the support column (31) is fixedly connected with the case (11), the fixed seat (32) is fixedly connected to a left end of the support column (31), the computer display (34) is clamped in the fixed seat (32), the support frame (35) is fixedly connected to an upper end of the support column (31), the sliding rod (37) is slidably nested in the support frame (35), the movable clamping seat (39) is fixedly connected to a lower end of the sliding rod (37), the movable clamping seat (39) is in clamped connection with the computer display (34), and the code scanner (311) is fixedly connected to a lower end of the support frame (35).

2. The sensing and digital display type weighing and code scanning integrated machine with a damping and dust-proof smart case according to claim 1, wherein the fan (16) is fixedly connected to an upper end of the case (11), and the fan (16) is connected with an external power supply by a wire.

3. The sensing and digital display type weighing and code scanning integrated machine with a damping and dust-proof smart case according to claim 1, wherein the case (11) is formed with the guide hole (12), and the guide rod (19) is slidably nested in the guide hole (12).

4. The sensing and digital display type weighing and code scanning integrated machine with a damping and dust-proof smart case according to claim 1, wherein the first spring (110) is sleeved on outer side of the guide rod (19), an upper end of the first spring (110) is in contact with a lower end of the host base (111), and a lower end of the first spring (110) is in contact with the case (11).

5. The sensing and digital display type weighing and code scanning integrated machine with a damping and dust-proof smart case according to claim 1, wherein the host base (111) is formed with the first clamping groove (112), and the first clamping groove (112) is in clamped connection with the computer host (113).

6. The sensing and digital display type weighing and code scanning integrated machine with a damping and dust-proof smart case according to claim 1, wherein the filter cartridge (114) is formed with the circular groove (115), and the efficient filter screen (116) is adhered in the circular groove (115).

7. The sensing and digital display type weighing and code scanning integrated machine with a damping and dust-proof smart case according to claim 1, wherein the fixed seat (32) is formed with the second clamping groove (33), and the second clamping groove (33) is in clamped connection with the computer display (34).

8. The sensing and digital display type weighing and code scanning integrated machine with a damping and dust-proof smart case according to claim 1, wherein the support frame (35) is formed with the through hole (36), the through hole (36) is slidably nested with the sliding rod (37), the second spring (38) is sleeved on an outer side of the sliding rod (37), an upper end of the second spring (38) is in contact with a lower end of the support frame (35), and a lower end of the second spring (38) is in contact with an upper end of the movable clamping seat (39).

9. The sensing and digital display type weighing and code scanning integrated machine with a damping and dust-proof smart case according to claim 1, wherein the movable clamping seat (39) is formed with the third clamping groove (310), and the third clamping groove (310) is in clamped connection with the computer display (34).
